(19) United States
(12) Patent Application Publication
(10) Pub. No.: US 2007/0166882 A1
(43) Pub. Date: Jul. 19, 2007

(54) Methods for fabricating chip-scale packages having carrier bonds

(76) Inventors: Tongbi Jiang, Boise, ID (US); Edward A. Schrock, Boise, ID (US)

Correspondence Address: TRASK BRITT, P.C./ MICRON TECHNOLOGY, P.O. BOX 2550, SALT LAKE CITY, UT, 84110, US

(21) Appl. No.: 11/716,464

(22) Filed: Mar. 9, 2007

Related U.S. Application Data
(62) Division of application No. 09/483,712, filed on Jan. 14, 2000.

(51) Int. Cl. H01L 21/00; H01L 21/44

(52) U.S. Cl. 438/112; 438/617; 257/E23.033; 257/E23.116

(57) ABSTRACT

A chip-scale package and method for making same. A pattern of conductive traces in the form of lead fingers is adhered to the active surface of a semiconductor die, preferably using a dielectric tape. The conductive traces are wire bonded to bond pads of the semiconductor die to establish electrical connections therebetween. Discrete conductive elements are then attached to the conductive traces in a pattern corresponding to a terminal pad pattern on a carrier substrate such as a printed circuit board. The semiconductor die, tape, conductive traces, wire bonds and interior portions of the discrete conductive elements are encapsulated to create a completed chip-scale package having an array of conductive connections protruding through the encapsulant.

### CROSS-REFERENCE TO RELATED APPLICATION

This application is a divisional of application Ser. No. 09,483,712, filed Jan. 14, 2000, pending, the disclosure of which is incorporated herein in its entirety by this reference.

### BACKGROUND OF THE INVENTION

1. Field of the Invention

This invention relates generally to chip-scale semiconductor packages. More particularly, this invention pertains to methods for fabricating low-cost chip-scale semiconductor packages in a ball grid array configuration using a lead frame as an interposer.

2. State of the Art

A chip-scale package (CSP) is a semiconductor die package having exterior dimensions (length, width, height) which are the same as, or only slightly larger than, the dimensions of the bare die itself. Such packages are relatively inexpensive to fabricate, and their small size conserves valuable “real estate” (space) on a carrier substrate such as a printed circuit board bearing a number of semiconductor dice of the same or different types.

The use of CSP's in the construction of larger, multi-die semiconductor devices provides certain advantages over the use of either bare dice or larger, conventional transfer-molded packages. The semiconductor die in a CSP is at least partially encapsulated and thereby protected, unlike the bare semiconductor dice used, for example, in a direct chip attach (DCA) assembly. This protection increases the physical robustness of the die and reduces the amount of care which must be used to store, test, manipulate and place the die on a carrier substrate or other higher-level packaging. This, in turn, reduces the costs required to fabricate a multi-chip module or other, more sophisticated electronic assembly because less expensive methods may be used to manipulate and place a CSP on a carrier. Likewise, CSPs are more resistant to damage during normal shipping and handling than bare semiconductor dice. The encapsulant surrounding the semiconductor die in a CSP protects the semiconductor die from moisture, dust and other environmental contaminants, thus resulting in a lower potential for environmentally-induced malfunctions and failures. In addition, leads or traces of a CSP may facilitate relocation and expansion of the pitch (spacing) of external electrical connections of the die by rerouting of the original bond pad connections to more convenient locations. The larger pitch is obtained by extending leads away from the originally-fabricated semiconductor die bond pad locations so that the external connections may be configured as an array, for example a ball grid array (BGA), of solder balls. Thus, a CSP offers all of the foregoing advantages over the use of a bare semiconductor die in semiconductor device assembly processes without significantly increasing the size of the entire package over that of the bare die and at a far lower cost than if conventional transfer-molded packaging approaches are employed.

In the current state of the art of chip-scale packaging, leads of a typical CSP extend out to the outer surface of the CSP, where they are at least partially exposed. One problem associated with such a configuration is that exposure of at least portions of the leads to the outer surface of the CSP may cause inadvertent connections when the CSP is connected to a carrier. Such inadvertent connections may short out the CSP or cause other, undesired results. Another problem has to do with the technique used to connect the CSP to a carrier. Typically, solder balls are arranged in a ball grid array (BGA) on the exposed portions of the leads of the CSP outside the encapsulating material in order to facilitate connection to a carrier substrate. Such fully-exposed solder balls are not as resilient or robust as a connection which would extend from within a CSP and be partially laterally surrounded by encapsulation. In addition, the ability to vary the size, pitch and configuration of a BGA in conventional CSP's is limited by the need to expose portions of the leads on the outside of the encapsulant, since the solder balls are placed after encapsulation of the die.

One example of a CSP as disclosed in U.S. Pat. No. 5,684,330 (hereinafter the “330 patent”) is illustrated in drawing FIG. 1. A CSP package 200 comprises a semiconductor die 210 to which is adhesively attached a circuit board 220 by a polyimide tape 230. The circuit board is characterized as a thin copper plate covered with an insulating material. The semiconductor die 210 is conductively connected to traces (not shown) on circuit board 220 by wire bonds 240. An outer surface 201 of the CSP 200 is defined by encapsulating the semiconductor die 210, tape 230, circuit board 220, and wire bonds 240 within an encapsulation material 260 such that conductive pads at the end of traces of the circuit board 220 extend to the outer surface 201 of the CSP 200. Following encapsulation of the CSP 200, solder is used to mechanically and electrically connect portions of circuit board 220 which are exposed outside of the encapsulation material to a carrier substrate such as a board for a multi-chip module. Although not described in the '330 patent, in some instances by others, the solder may be placed as solder balls 250 on circuit board 220 in a ball grid array to complete the CSP 200, while in other instances, the solder may be placed on a carrier substrate and the circuit board 220 placed in contact therewith for reflow.

While wire bonding is a low-cost and high-yield process for fabricating CSP's, including a CSP using solder ball interconnections to a carrier substrate such as is disclosed in the '330 patent, using a printed circuit board as an “interposer” for rerouting external electrical connections from the bond pads of a semiconductor die to new locations presents significant challenges in terms of selection of a suitable adhesive material used to secure the circuit board to the active surface of the die as well as the board-to-die lamination process. On the one hand, a low Tg adhesive (low glass transition temperature adhesive as the term Tg is applied and used in relation to an adhesive) is required to effect a low temperature die attach process to accommodate the relatively limited temperature tolerance exhibited by printed circuit boards. On the other hand, a high Tg adhesive is required to achieve a predictable, high wire bond yield. With a BT resin laminate circuit board containing a mixture of bismaleimide triazine resins so that it exhibits higher thermal stability than FR-4 epoxy-glass laminate circuit boards, and using commercially-available Taiyo solder mask technology, a lamination process temperature of 250° C. or more is required to achieve adequate adhesion between the dielectric tape and the circuit board and between the tape and the semiconductor die. Such high processing temperatures may in some instances lead to low wire bond, encapsulation and solder placement yields due to oxidation, contamination and degradation of the bond pads, solder ball pads and polymers used in the circuit board.

### BRIEF SUMMARY OF THE INVENTION

According to the invention, a chip-scale package is provided including a semiconductor die having bond pads on the active surface thereof, a semiconductor die package, and a metal lead frame including lead fingers dielectrically attached to the active surface, the lead fingers being connected, preferably by wire bonds, to bond pads on the active surface of the semiconductor die. Carrier bonds in the form of discrete conductive elements such as solder balls, conductive epoxy bumps or conductor-filled epoxy bumps are then attached to the lead fingers to define an array of external connections for the die. The entire package is then encapsulated in an insulating material such that a portion of each of the discrete conductive elements extends through the encapsulant.

The CSP of the present invention is formed by first dielectrically attaching lead fingers of a suitably-configured lead frame to the active surface of a semiconductor die in a leads-over-chip (LOC) configuration using a dielectric adhesive in the form of a film or a dual-sided adhesive tape. The lead fingers are then electrically connected to the bond pads on the active surface of the semiconductor die. Carrier bonds in the form of discrete individual conductive elements, such as the aforementioned solder or epoxy, are directly attached to the lead fingers in a desired pattern to form an array. Encapsulation of the package is then accomplished with a material having a low modulus of elasticity using encapsulation techniques for such a material. The resulting CSP is an encapsulated semiconductor die package having a pattern of discrete conductive elements protruding therefrom through the encapsulant material.

### BRIEF DESCRIPTION OF THE SEVERAL VIEWS OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 illustrates a cross-sectional view of an exemplary, prior art chip-scale package;

FIG. 2 illustrates a top elevation of one embodiment of the chip-scale package of the present invention;

FIG. 3 illustrates a cross-sectional view of the embodiment of FIG. 2, taken along line 3-3;

FIG. 4 illustrates a cross-sectional view of an alternative embodiment of the chip-scale package of the present invention;

FIG. 5 illustrates a top-down view of an alternative embodiment of the chip-scale package of the present invention having staggered discrete conductive connections; and

FIG. 6 illustrates a side view of the chip-scale package of FIG. 5 connected to a carrier substrate.

### DETAILED DESCRIPTION OF THE INVENTION

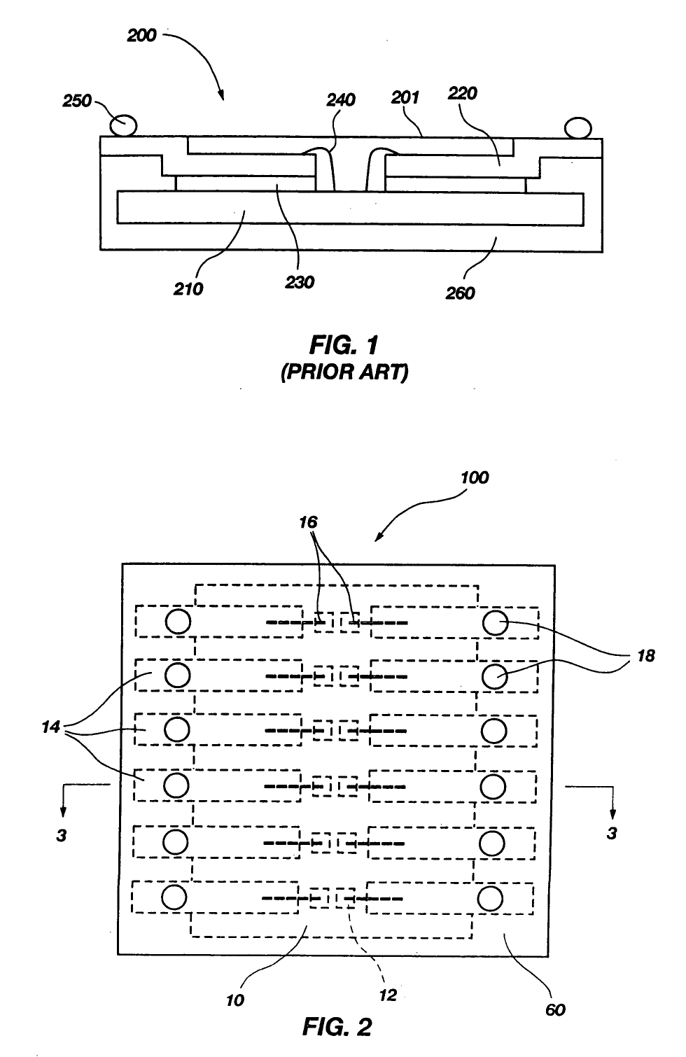

illustrated in drawing FIG. 2 is a plan view of an embodiment of a chip-scale package 100 of the present invention. Bond pads 12 of semiconductor die 10 are conductively connected to metal lead fingers 14 by wire bonds 16, which may comprise gold, aluminum or alloys thereof as known in the art. A discrete conductive element 18 (also termed a carrier bond) such as a solder ball is secured to each of the lead fingers 14. The assembly is encapsulated within a suitable dielectric material, but for the outer ends of discrete conductive elements 18, which protrude through the encapsulant.

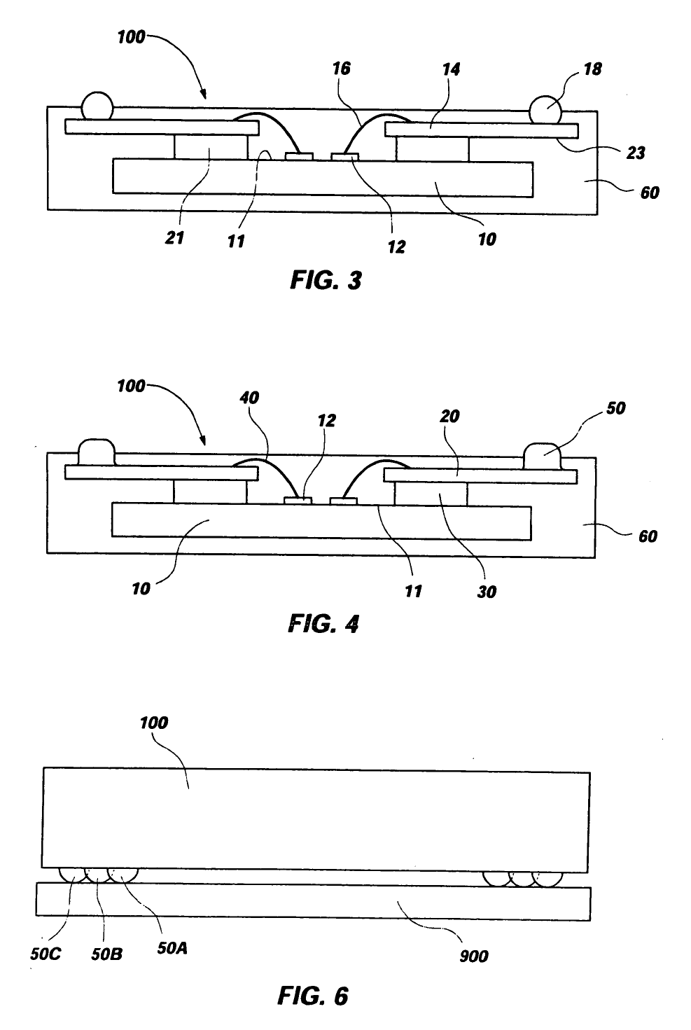

Embodiment 100 of the chip-scale package of the present invention is further illustrated by drawing FIG. 3 which comprises a cross-sectional view of drawing FIG. 2. With reference to drawing FIG. 3, lead fingers 14 are attached to the active surface 11 of semiconductor die 10 by a dielectric adhesive structure 21 disposed therebetween. The dielectric adhesive structure 21 may comprise a polyimide film, or a dielectric tape such as a polyimide having an adhesive on each side thereof to respectively adhere to active surface 11 and the undersides 23 of lead fingers 14. As noted with respect to drawing FIG. 2 but better shown in drawing FIG. 3, outer portions of each discrete conductive element 18 protrude beyond the encapsulation material 60 so that the conductive elements 18 may be mechanically and electrically connected in a flip-chip (active surface down) orientation to a carrier substrate 900 such as a printed circuit board (see drawing FIG. 6).

Referring to drawing FIG. 4, a cross-sectional view of a further embodiment of the present invention, semiconductor die 10 has an active surface 11 upon which bond pads 12 are located. The bond pads 12 provide a location on the active surface 11 of the semiconductor die 10 for attaching conductive bonds 40. The semiconductor die 10 may comprise any semiconductor die used in DCA processes or in typical CSP configurations. Such semiconductor dice 10 include, but are not limited to, memory devices, such as dynamic random access memory (DRAM), static random access memory (SRAM), and other types of semiconductor dice, including, without limitation, microprocessors and logic chips, which may be embedded within a chip-scale package 100.

The conductive traces 20 may each be an individual conductive trace or a lead frame member of the type commonly used with existing leads-over-chip (LOC) technology. Typically, the conductive trace 20 of the CSP 100 is a metallic lead frame member, having an upper and a lower surface, which is attached to the semiconductor die 10 using LOC lamination technology as previously described. The lower surface of the conductive trace 20 is disposed against the dielectric element 30 whereby the conductive trace 20 is attached to the active surface 11 of the semiconductor die 10 using dielectric element 30. A carrier bond 50 or other electrically conductive element may be attached to the upper surface of the conductive trace 20 to facilitate electrical connection of the CSP 100 with a carrier substrate 900 (shown in drawing FIG. 6).

Typically, a substantially non-conductive material, such as a polyimide tape, is used as the dielectric element 30. The dielectric element 30 is disposed between the active surface 11 of the semiconductor die 10 and the lower surface of the conductive trace 20. Attachment may be effected by the application of heat to form an attachment between the dielectric element 30 and the semiconductor die 10 and conductive trace 20. The dielectric element 30 may also have the surfaces thereof adhesively coated to help facilitate the attachment of a conductive trace 20 to a semiconductor die 10.

Dielectric materials used in existing LOC technology are the preferred dielectric element 30. Such LOC materials and techniques are preferred because they allow lamination to occur at a temperature which prevents unwanted oxidation, contamination, and degradation. However, it is realized that other lamination techniques and attachment techniques may be used to attach a conductive trace 20 to a semiconductor die 10 to create the CSP 100 of the present invention.

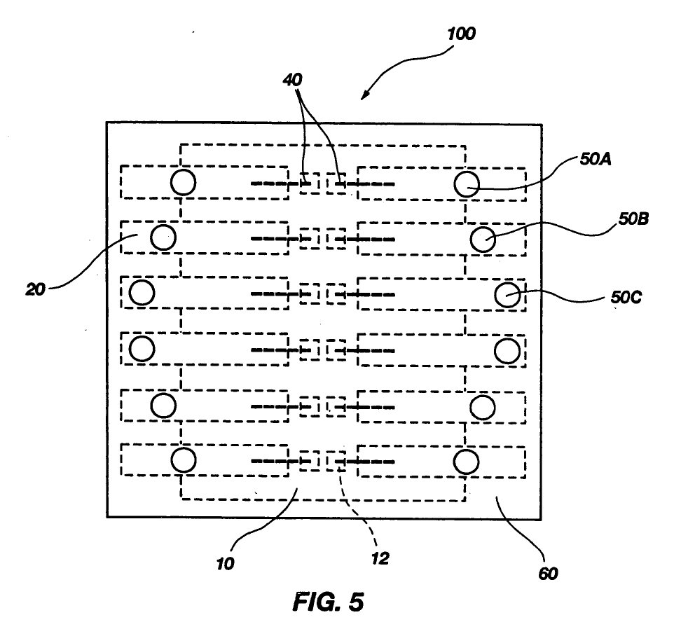

The conductive bond 40 is typically a wire bond, formed using wire bonding methods and materials known in the art. The conductive bond 40 acts as an electrical connection between the semiconductor die 10 and the conductive trace 20. In the preferred embodiment, a wire bond 40, typically gold or aluminum, is formed between conductive trace 20 and a bond pad 12 on the active surface 11 of semiconductor die 10. It is also understood that conductive bond 40 may be created using TAB bonding techniques, thermocompression bonding techniques where traces 20 extend over bond pads 12 as shown in broken lines (FIG. 5), or any other conductive bonding techniques used or developed in the art.

In the present invention, a carrier bond 50 is attached to the upper surface of conductive trace 20 to provide a conductive connection between the chip-scale package 100 and a carrier substrate 900, such as a printed circuit board, as shown in drawing FIG. 6. To form the required conductive connection, the carrier bond 50 must be comprised of a conductive material such as gold or copper, but may be formed using any conductive material. Exemplary carrier bonds 50 include solder balls (as illustrated in drawing FIG. 3), conductive resins or polymers containing conductive particles, such as silver or gold (as illustrated in drawing FIG. 4), and the like. The carrier bond 50 may be deposited on conductive trace 20 using any method known in the art.

The chip-scale package 100 is contained within an encapsulation material 60. The encapsulation material 60 surrounds the semiconductor die 10, the conductive traces 20, the dielectric element 30, the conductive bonds 40, and a portion of the carrier bonds 50. A portion of each carrier bond 50 extends or protrudes outward from the encapsulation material 60 to match a pattern on a carrier substrate such as carrier substrate 900. The encapsulation material 60 is preferably a material having a low modulus of elasticity, such as CNB777-47 encapsulant offered by Dexter Electronic Materials, City of Industry, California.

Unlike the prior art, the carrier bonds 50 of the present invention are positioned prior to the encapsulation of the CSP 100. Positioning the carrier bonds 50 prior to encapsulation allows the carrier bonds 50 to be attached at any point along the conductive trace 20, thus providing a greater variety of possible patterns for the carrier bonds 50. This is an advantage over the prior art lead configuration as depicted in drawing FIG. 1, because the CSPs of the prior art are limited to using the surfaces of the circuit board 220 which remain exposed after encapsulation. Likewise, encapsulation of the carrier bonds 50 reinforces and supports the attachment between the carrier bonds 50 and the conductive trace 20. In addition, encapsulation of the entire conductive trace 20 helps to prevent unwanted shorts within the CSP 100 caused by inadvertent conductive connections between the exposed circuit board 220 of the prior art and a carrier substrate 900.

illustrated in drawing FIG. 5 is an alternative pattern of carrier bond 50 placement on conductive traces 20. The current invention allows placement of the carrier bonds 50 along the entire span of conductive traces 20. Depending upon the conductive connection pattern desired to electrically connect a chip-scale package 100 of the present invention to a carrier substrate 900, carrier bonds 50 are attached to conductive traces 20 at locations to match the desired trace or terminal pad pattern on the carrier substrate 900. As shown in drawing FIG. 5, three different placements of carrier bonds 50, in positions 50A, 50B, and 50C, respectively, are illustrated as an example of one possible pattern of carrier bonds 50 which could be created using the present invention. It is understood that the variations in patterns are only limited by the configuration and surface area of each of the conductive traces 20 used to fabricate the CSP 100.

Illustrated in drawing FIG. 6 is an attachment of a CSP 100, having a carrier bond 50 pattern as depicted in drawing FIG. 5, with a carrier substrate 900, such as a printed circuit board. Carrier bonds 50A, 50B, and 50C represent carrier bonds 50 placed in a pattern or array corresponding to the pattern of drawing FIG. 5, in order to match the desired trace or terminal pad pattern of the carrier substrate 900. A CSP 100 is attached to a carrier substrate 900 using heat to form the desired electrical connection between the carrier bonds 50 of the CSP 100 and carrier substrate 900.

The process of fabricating a chip-scale package 100 of the present invention begins with a die lamination step wherein a plurality of conductive traces 20, preferably configured as lead fingers in a lead frame configuration, are laminated to a semiconductor die 10 with a dielectric element 30 therebetween. Each conductive trace 20 is bonded to bond pads 12 on an active surface 11 of the semiconductor die 10 using a conductive bond 40. The carrier bonds 50 are attached to each individual conductive trace 20 in a pattern corresponding to a desired attachment pattern on a carrier substrate 900. After a trimming operation wherein the conductive traces (lead fingers) 20 are severed from a surrounding lead frame, the chip-scale package 100 is completed by encapsulating the semiconductor die 10, the dielectric element 30, the conductive traces 20, the conductive bonds 40 and inner portions of the carrier bonds 50 within an encapsulation material 60.

Attachment of a carrier bond 50 to the conductive traces 20 of a CSP 100 prior to encapsulation helps to protect and support the attachment point of the carrier bonds 50 with the conductive trace 20. Such protection decreases the occurrence of defective CSPs and improves the storage and handling capabilities of the completed CSP devices. Likewise, encapsulation of the non-bonded areas of the conductive traces 20 eliminates the possibility of inadvertent conductive connections and electrical shorts following attachment of a CSP 100 to a carrier substrate 900.

Having thus described certain preferred embodiments of the present invention, it is to be understood that the invention defined by the appended claims is not to be limited by particular details set forth in the above description, as many apparent variations thereof are possible without departing from the spirit or scope thereof as hereinafter claimed.

What is claimed is:

1. A method for fabricating a chip-scale package comprising:
providing a semiconductor die having an active surface having at least one bond pad disposed thereon;
providing at least one conductive trace having an upper surface and a lower surface;
dielectrically attaching at least a portion of the lower surface of said at least one conductive trace to a portion of the active surface of said semiconductor die;
attaching a conductive bond member between said at least one conductive trace and the at least one bond pad disposed on the active surface of said semiconductor die;
attaching at least one carrier bond to a portion of the upper surface of said at least one conductive trace; and
encapsulating at least portions of said semiconductor die, said at least one conductive trace, said conductive bond and a portion of said at least one carrier bond.

2. The method for fabricating a chip-scale package as in claim 1, further comprising forming said at least one conductive trace as a lead frame element.

3. The method for fabricating a chip-scale package as in claim 1, further comprising forming said at least one conductive trace of a conductive metal.

4. The method for fabricating a chip-scale package as in claim 1, further comprising forming said conductive bond member as a wire bond.

5. The method for fabricating a chip-scale package as in claim 1, further comprising forming said conductive bond member as a TAB bond.

6. The method for fabricating a chip-scale package as in claim 1, further comprising forming said at least one carrier bond as a solder ball.

7. The method for fabricating a chip-scale package as in claim 1, further comprising forming said at least one carrier bond comprises an electrically conductive or conductor-filled polymer.

8. The method for fabricating a chip-scale package as in claim 1, wherein said dielectrically attaching is effected using a polyimide tape.

9. A method for fabricating a chip-sized package as in claim 1, wherein the step of dielectrically attaching at least a portion of the lower surface of said conductive trace to a portion of the active surface of said semiconductor die further comprises:
providing a dielectric material having an upper surface and a lower surface;
attaching at least a portion of the lower surface of said joint material to at least a portion of the active surface of said semiconductor die; and
attaching at least a portion the lower surface of said at least one conductive trace to at least a portion of the upper surface of said joint material.
